(19) United States
(12) Patent Application Publication
(10) Pub. No.: US 2017/0194525 A1
(43) Pub. Date: Jul. 6, 2017

(54) HIGH POWER SOLAR CELL MODULE

(71) Applicant: Win Win Precision Technology Co., Ltd., Hsinchu City (TW)

(72) Inventors: Cheng-Lien Wang, Taoyuan City (TW); I-Liang Chen, Hsinchu County (TW); Chien-Chun Hsieh, Hualien County (TW)

(73) Assignee: Win Win Precision Technology Co., Ltd., Hsinchu City (TW)

(21) Appl. No.: 15/397,734

(22) Filed: Jan. 4, 2017

(30) Foreign Application Priority Data
Jan. 4, 2016 (TW) 105100020

(51) Int. Cl. H01L 31/05; H01L 31/0232; H01L 31/02; H01L 31/0236; H01L 31/054; H01L 31/077

(52) U.S. Cl. CPC H01L 31/0508; H01L 31/0547; H01L 31/077; H01L 31/0201; H01L 31/02366; H01L 31/02327; H01L 31/0512

(57) ABSTRACT

A high power solar cell module including a cover plate, a back plate, a first encapsulation, a second encapsulation, a plurality of N type hetero-junction solar cells, and a plurality of reflective connection ribbons is provided. The back plate is opposite to the cover plate. The first encapsulation is located between the cover plate and the back plate. The second encapsulation is located between the first encapsulation and the back plate. The N type hetero-junction solar cells and the reflective connection ribbons are located between the first encapsulation and the second encapsulation, and any two adjacent N type hetero junction solar cells are connected in series along a first direction by at least one of the reflective connection ribbons, wherein each of the reflective connection ribbons has a plurality of triangle columnar structures. Each of the triangle columnar structures points to the cover plate and extends along the first direction.

### CROSS-REFERENCE TO RELATED APPLICATION

This application claims the priority benefit of Taiwan application serial no. 105100020, filed on Jan. 4, 2016. The entirety of the above-mentioned patent application is hereby incorporated by reference herein and made a part of this specification.

### BACKGROUND OF THE INVENTION

Field of the Invention

The invention relates to a solar cell module, and particularly relates to a high power solar cell module.

Description of Related Art

In recent years, along with rising awareness of an environmental protection and shortage of fossil fuels, alternative energy and renewable energy become hot issues. Since a solar cell may convert solar energy into electric power, and none harmful substance such as carbon dioxide or nitride, etc. is produced during the photoelectric generation process, the solar cell becomes a very important and popular part in renewable energy research.

Generally, the solar cell includes an active layer and electrode layers disposed at two opposite sides of the active layer. When a light beam irradiates the solar cell, the active layer may produce electron-hole pairs under the irradiation of the light energy. Electrons and holes respectively move towards the two electrode layers under a function of an electric field between the two electrode layers to enable an electrical energy storage state. If a load circuit is connected, the electric energy can be output to drive an electronic device.

Since the current solar cell module has limited output power, it is hard to provide electric power for home and industrial needs. Therefore, to improve the output power of the solar cell module becomes a trend of the future.

### SUMMARY OF THE INVENTION

The invention provides a high power solar cell module, which has a high output power.

The invention provides a high power solar cell module including a cover plate, a back plate, a first encapsulation, a second encapsulation, a plurality of N-type hetero-junction solar cells, and a plurality of reflective connection ribbons. The back plate is opposite to the cover plate. The first encapsulation is located between the cover plate and the back plate. The second encapsulation is located between the first encapsulation and the back plate. The N-type hetero-junction solar cells and the reflective connection ribbons are located between the first encapsulation and the second encapsulation, and any two adjacent N-type hetero-junction solar cells are connected in series along a first direction by at least one of the reflective connection ribbons, where each of the reflective connection ribbons has a plurality of triangle columnar structures. Each of the triangle columnar structures points to the cover plate and extends along the first direction.

In an embodiment of the invention, each of the N-type hetero junction solar cells includes an N-type silicon substrate, a first intrinsic amorphous silicon layer, a second intrinsic amorphous silicon layer, a P-type heavily doped hydrogenated amorphous silicon layer, an N-type heavily doped hydrogenated amorphous silicon layer, a first transparent conductive layer and a second transparent conductive layer. The N-type silicon substrate has a first surface and a second surface. The second surface is opposite to the first surface and is located between the first surface and the back plate. The first intrinsic amorphous silicon layer is disposed on the first surface. The second intrinsic amorphous silicon layer is disposed on the second surface. The P-type heavily doped hydrogenated amorphous silicon layer is disposed on the first intrinsic amorphous silicon layer. The N-type heavily doped hydrogenated amorphous silicon layer is disposed on the second intrinsic amorphous silicon layer. The first transparent conductive layer is disposed on the P-type heavily doped hydrogenated amorphous silicon layer. The second transparent conductive layer is disposed on the N-type heavily doped hydrogenated amorphous silicon layer.

In an embodiment of the invention, the reflective connection ribbons are respectively fixed on the first transparent conductive layer and the second transparent conductive layer through a thermosetting conductive adhesive layer.

In an embodiment of the invention, each of the N-type hetero-junction solar cells further includes a first metal layer. The first metal layer is disposed on the first transparent conductive layer, and the first metal layer includes a plurality of first finger-like electrodes arranged along the first direction.

In an embodiment of the invention, the reflective connection ribbons are respectively fixed on the first finger-like electrodes through a thermosetting conductive adhesive layer.

In an embodiment of the invention, the first metal layer further includes at least one first bus electrode. Each first bus electrode extends along the first direction. The reflective connection ribbons are respectively fixed on the first bus electrodes of the N-type hetero-junction solar cells through a thermosetting conductive adhesive layer.

In an embodiment of the invention, each first bus electrode includes at least one opening.

In an embodiment of the invention, each of the N-type hetero-junction solar cells further includes a second metal layer. The second metal layer is disposed on the second transparent conductive layer, and the reflective connection ribbons are respectively fixed on the second metal layer through a thermosetting conductive adhesive layer.

In an embodiment of the invention, the second metal layer includes a plurality of second finger-like electrodes arranged along the first direction.

In an embodiment of the invention, the reflective connection ribbons are respectively fixed on the second finger-like electrodes through the thermosetting conductive adhesive layer.

In an embodiment of the invention, the second metal layer further includes at least one second bus electrode. Each second bus electrode extends along the first direction. The reflective connection ribbons are respectively fixed on the second bus electrodes of the N-type hetero junction solar cells through the thermosetting conductive adhesive layer.

In an embodiment of the invention, each second bus electrode includes at least one opening.

In an embodiment of the invention, a surface of the back plate facing the cover plate has a plurality of microstructures. The microstructures reflect the light beam entering the high power solar cell module from the cover plate, and the light beam is reflected to one of the N-type hetero junction solar cells from the cover plate through total internal reflection.

In an embodiment of the invention, a width of each of the reflective connection ribbons ranges between 0.5 mm and 1.5 mm, and a thickness of each of the reflective connection ribbons ranges between 0.15 mm and 0.3 mm.

In an embodiment of the invention, each of the reflective connection ribbons further has a reflective layer. The reflective layer is disposed on the triangle columnar structures, and a reflectivity of the reflective layer is higher than 60%, and a thickness of the reflective layer ranges between 0.3 μm and 10 μm.

In an embodiment of the invention, the reflective layer is a silver reflective layer.

According to the above descriptions, since the N-type hetero-junction solar cells have a high photoelectric conversion efficiency, and the triangle columnar structures of the reflective connection ribbons avail improving a light usage rate, the high power solar cell module of the invention has a high output power.

In order to make the aforementioned and other features and advantages of the invention comprehensible, several exemplary embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A is a partial cross-sectional view of a high power solar cell module according to an embodiment of the invention.

FIG. 1B is a first partial top view of the high power solar cell module of FIG. 1A.

FIG. 1C is a cross-sectional view viewing along a section line I-I′ of FIG. 1B.

FIG. 2A is a second partial top view of the high power solar cell module of FIG. 1A.

FIG. 2B and FIG. 2C are respectively cross-sectional views viewing along section lines II-II′ and III-III′ of FIG. 2A.

FIG. 3A and FIG. 3B are respectively other cross-sectional views viewing along section lines II-II′ and III-III′ of FIG. 2A.

FIG. 4A is a third partial top view of the high power solar cell module of FIG. 1A.

FIG. 4B is a cross-sectional view viewing along a section line IV-IV′ of FIG. 4A.

FIG. 5A is a fourth partial top view of the high power solar cell module of FIG. 1A.

FIG. 5B is a cross-sectional view viewing along a section line V-V′ of FIG. 5A.

### DESCRIPTION OF EMBODIMENTS

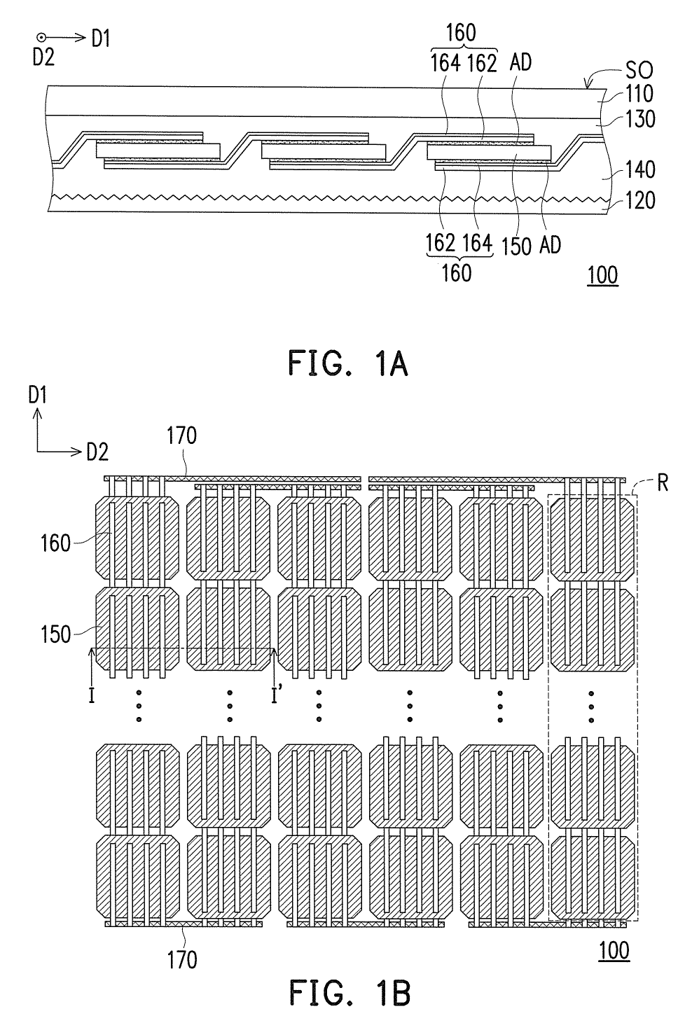

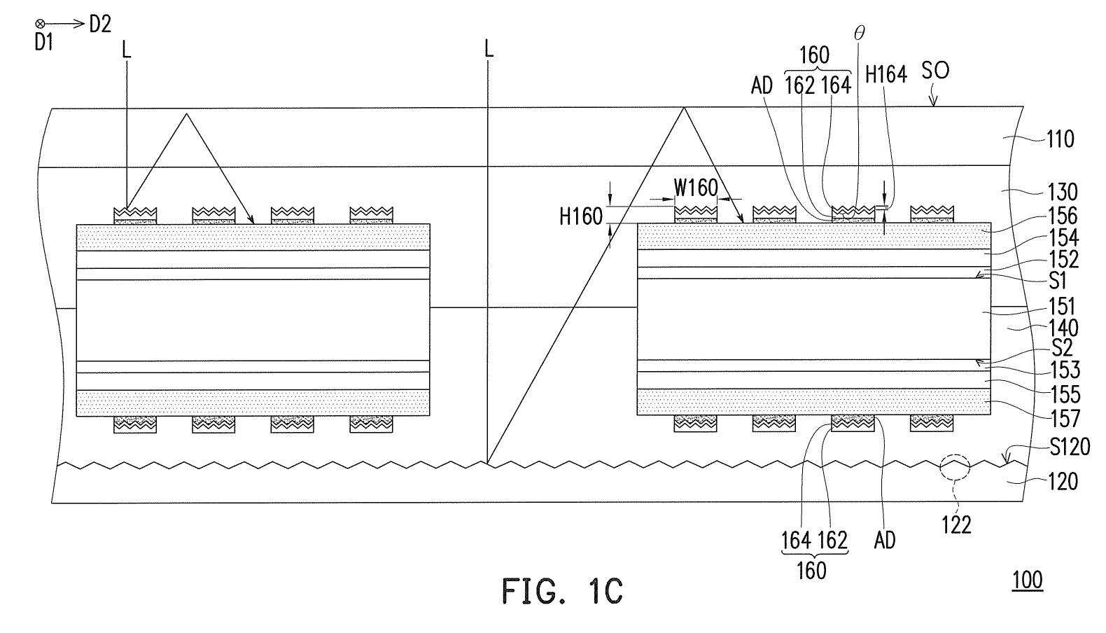

FIG. 1A is a partial cross-sectional view of a high power solar cell module according to an embodiment of the invention. FIG. 1B is a first partial top view of the high power solar cell module of FIG. 1A, where a cover plate and a first encapsulation of FIG. 1A are omitted in FIG. 1B. FIG. 1C is a cross-sectional view viewing along a section line I-I′ of FIG. 1B. Referring to FIG. 1A to FIG. 1C, a high power solar cell module 100 includes a cover plate 110, a back plate 120, a first encapsulation 130, a second encapsulation 140, a plurality of N-type hetero-junction solar cells 150, and a plurality of reflective connection ribbons 160.

The cover plate 110 can be a rigid substrate with a high mechanical strength, so as to protect the devices under the cover plate 110. Moreover, a material of the cover plate 110 is a transparent material, such that a light beam L from the outside may penetrate through the cover plate 110, and is absorbed by the N-type hetero-junction solar cells 150. The transparent material refers to a general material with a high light transmittance, and is not limited to the material with a light transmittance of 100%. For example, the cover plate 110 can be a low iron glass substrate, though the invention is not limited thereto.

The back plate 120 and the cover plate 110 are opposite to each other. The back plate 120 can also be a rigid substrate with a high mechanical strength to protect the devices above the back plate 120. Moreover, a material of the back plate 120 may adopt a transparent material or a non-transparent material. When the material of the back plate 120 adopts the transparent material, the high power solar cell module 100 can be a double-side light receiving solar cell module, where the light beam L from the outside can penetrate through the cover plate 110 and the back plate 120, and is absorbed by the N-type hetero-junction solar cells 150. When the material of the back plate 120 adopts the non-transparent material, the high power solar cell module 100 can be a single-side light receiving solar cell module, and the light beam L from the outside may penetrate through the cover plate 110, and is absorbed by the N-type hetero junction solar cells 150.

In the embodiment, the high power solar cell module 100 is, for example, a single-side light receiving solar cell module, and the back plate 120 adopts a reflective back plate to improve the light usage rate. Referring to FIG. 1C, a surface 120 of the back plate 120 facing the cover plate 110 may have a plurality of microstructures 122. The microstructures 122 are adapted to reflect the light beam L entering the high power solar cell module 100 from the cover plate 110, such that the light beam L is propagated toward the cover plate 110, and is reflected by the cover plate 110 to one of the N-type hetero-junction solar cells 150 through total internal reflection. For example, the light beam L is reflected by an outer surface SO of the cover plate 110 through the total internal reflection, and is propagated toward the N-type hetero-junction solar cell 150. Therefore, the reflective back plate avails improving a chance that the light beam L is absorbed by the N-type hetero-junction solar cells 150.

The first encapsulation 130 is located between the cover plate 110 and the back plate 120. The second encapsulation 140 is located between the first encapsulation 130 and the back plate 120. Specifically, the first encapsulation 130 and the second encapsulation 140 are respectively located at two opposite surfaces of the N-type hetero junction solar cells 150 for encapsulating the N-type hetero-junction solar cells 150. A material of the first encapsulation 130 and the second encapsulation 140 adopts a material that is adapted to barrier vapour and oxygen in the environment. Moreover, the material of the first encapsulation 130 and the second encapsulation 140 may adopt a material with a high light transmittance, and the material may be a material that is pervious to ultraviolet light. In this way, a chance that the light beam L penetrates through the first encapsulation 130 and is propagated to the N-type hetero-junction solar cell 150 is improved, and a chance that the light beam L reflected by the back plate 120 penetrates through the second encapsulation 140 and is propagated to the N-type hetero-junction solar cell 150 is improved. For example, a light transmittance of the first encapsulation 130 and the second encapsulation 140 for the light beam with a wavelength ranges between 250 nm and 340 nm is higher than 70%. Moreover, the material of the first encapsulation 130 and the second encapsulation 140 can be Ethylene Vinyl Acetate (EVA), Poly Vinyl Butyral (PVB), Polyolefin, Polyurethane, silicone, or a transparent polymer insulation adhesive.

The N-type hetero-junction solar cells 150 are located between the first encapsulation 130 and the second encapsulation 140. FIG. 1C illustrates one implementation of the N-type hetero-junction solar cell 150, though the structure of the N-type hetero-junction solar cell 150 is not limited to the structure shown in FIG. 1C. Referring to FIG. 1C, each of the N-type hetero-junction solar cells 150 may include an N-type silicon substrate 151, a first intrinsic amorphous silicon layer 152, a second intrinsic amorphous silicon layer 153, a P-type heavily doped hydrogenated amorphous silicon layer 154, an N-type heavily doped hydrogenated amorphous silicon layer 155, a first transparent conductive layer 156 and a second transparent conductive layer 157.

The N-type silicon substrate 151 has a first surface S1 and a second surface S2. The second surface S2 is opposite to the first surface Si and is located between the first surface S1 and the back plate 120. At least one of the first surface S1 and the second surface S2 may selectively form a textured surface to improve an absorption rate of the light beam L, though the invention is not limited thereto.

The first intrinsic amorphous silicon layer 152 is disposed on the first surface S1. The second intrinsic amorphous silicon layer 153 is disposed on the second surface S2. The P-type heavily doped hydrogenated amorphous silicon layer 154 is disposed on the first intrinsic amorphous silicon layer 152. The N-type heavily doped hydrogenated amorphous silicon layer 155 is disposed on the second intrinsic amorphous silicon layer 153. The first transparent conductive layer 156 is disposed on the P-type heavily doped hydrogenated amorphous silicon layer 154. The second transparent conductive layer 157 is disposed on the N-type heavily doped hydrogenated amorphous silicon layer 155. A material of the first transparent conductive layer 156 and the second transparent conductive layer 157 is a transparent conductive material, for example, a metal oxide. The metal oxide can be indium tin oxide, indium zinc oxide, aluminium tin oxide, aluminium zinc oxide, indium germanium zinc oxide, or other suitable oxides, or a stacked layer of at least two of the aforementioned oxides. In an embodiment, the N-type hetero-junction solar cell 150 may further include at least one metal layer, for example, a back surface field (BSF) is configured on the second transparent conductive layer 157 to improve a collection rate of carriers.

The reflective connection ribbons 160 are located between the first encapsulation 130 and the second encapsulation 140, and any two adjacent N-type hetero-junction solar cells 150 are connected in series along a first direction D1 by at least one of the reflective connection ribbons 160 to form a plurality of cell strings R arranged along a second direction D2. The second direction D2 and the first direction D1 are intersected, and are, for example, perpendicular to each other, though the invention is not limited thereto. In the embodiment, any two adjacent N-type hetero junction solar cells 150 are connected in series along the first direction D1 by four of the reflective connection ribbons 160, though the invention is not limited thereto.

Each of the reflective connection ribbons 160 has a plurality of triangle columnar structures 162. Each of the triangle columnar structures 162 points to the cover plate 110 and extends along the first direction D1. A shape of each of the triangle columnar structures 162 can be an isosceles triangle. In the embodiment, a vertex angle θ of each of the triangle columnar structures 162, for example, ranges between 60 degrees and 90 degrees. Moreover, a width W160 of each of the reflective connection ribbons 160 ranges between 0.5 mm and 1.5 mm, and a thickness H160 of each of the reflective connection ribbons 160 ranges between 0.15 mm and 0.3 mm, though the invention is not limited thereto.

The vertex angle θ can be designed in collaboration with the number of the reflective connection ribbons 160 corresponding to each of the N-type hetero-junction solar cells 150, so as to optimize the light usage efficiency. To be specific, the light beam L irradiated to the reflective connection ribbons 160 is reflected by the triangle columnar structures 162 and transmitted to the cover plate 110, so that by properly adjusting the vertex angle θ, the light beam L transmitted to the cover plate 110 may occur total internal reflection at the cover plate 110 (for example, at the outer surface SO), and has a chance of being transmitted to the N-type hetero-junction solar cell 150 again. By suitably adjusting the number of the reflective connection ribbons 160 (i.e. modulating the spacing of the reflective connection ribbons 160), the light beam L totally reflected at the cover plate 110 can be transmitted to a place between two adjacent reflective connection ribbons 160, and is absorbed by the N-type hetero-junction solar cell 150. Therefore, by adjusting the number of the reflective connection ribbons 160 corresponding to each of the N-type hetero-junction solar cells 150 and the vertex angle θ of the triangle columnar structures 162, the light usage rate of the embodiment can be optimized, so as to improve an output power of the high power solar cell module 100.

In order to closely bond the reflective connection ribbons 160 and the N-type hetero-junction solar cell 150, the reflective connection ribbons 160 are respectively fixed on the N-type hetero-junction solar cells 150 through a thermosetting conductive adhesive layer AD. For example, spray or screen printing method may be used so that the thermosetting conductive adhesive layer AD connects the reflective connection ribbons 160 and the N-type hetero-junction solar cells 150. In the embodiment, the reflective connection ribbons 160 are respectively fixed on the first transparent conductive layer 156 and the second transparent conductive layer 157 through the thermosetting conductive adhesive layer AD, though the invention is not limited thereto. Under the structure that the back surface field is configured on the second transparent conductive layer 157, the reflective connection ribbons 160 can be respectively fixed on the back surface field through the thermosetting conductive adhesive layer AD. The thermosetting conductive adhesive layer AD can be any adhesive layer containing conductive particles and may be cured through a heating process. For example, the conductive particles may be metal particles containing a tin alloy. In the cell string process, the metal particles may be softened or melted by heating (at a temperature of 150° C. or higher), and the metal particles may be agglomerated and polymerized. Then, the resin in the thermosetting conductive adhesive layer AD may be solidified (or hardened) by the lamination process, so as to connect the reflective connection ribbons 160 and the N-type hetero junction solar cells 150. For example, the thermosetting conductive adhesive layer AD can be a conductive paste recorded in the Taiwan Patent No. 1284328, though the invention is not limited thereto.

Moreover, each of the reflective connection ribbons 160 may further has a reflective layer 164, so as to further improve the reflectivity of the reflective connection ribbons 160. The reflective layer 164 is disposed on the triangle columnar structures 162, and a reflectivity of the reflective layer 164 is higher than 60%, and a thickness H164 of the reflective layer 164 ranges between 0.3 μm and 10 μm. For example, the reflective layer 164 is a silver reflective layer, though the invention is not limited thereto.

Since the N-type hetero-junction solar cells 150 has a high photoelectric conversion efficiency, and the triangle columnar structures 162 of the reflective connection ribbons 160 avail improving the light usage rate, the high power solar cell module 100 may have a high output power.

According to different requirements, the high power solar cell module 100 may further includes components that are known in this field, for example, a plurality of bus ribbons 170 (referring to FIG. 1B) used for connecting the cell strings R in series, a bypass diode (not shown), a connecting box (not shown), etc., which will not further illustrated.

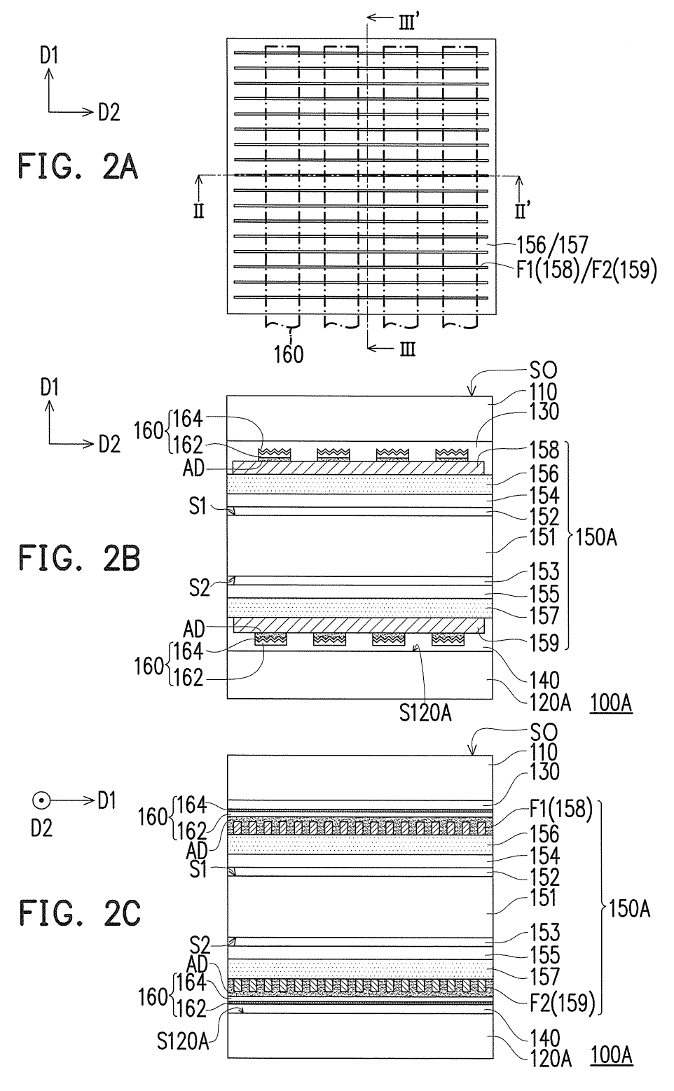

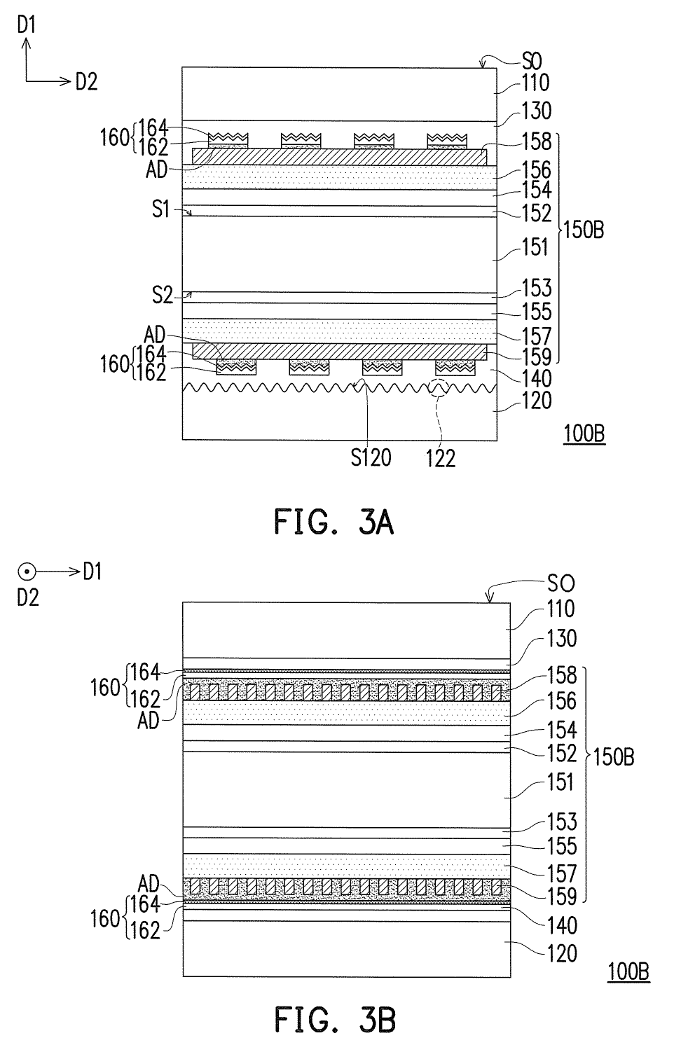

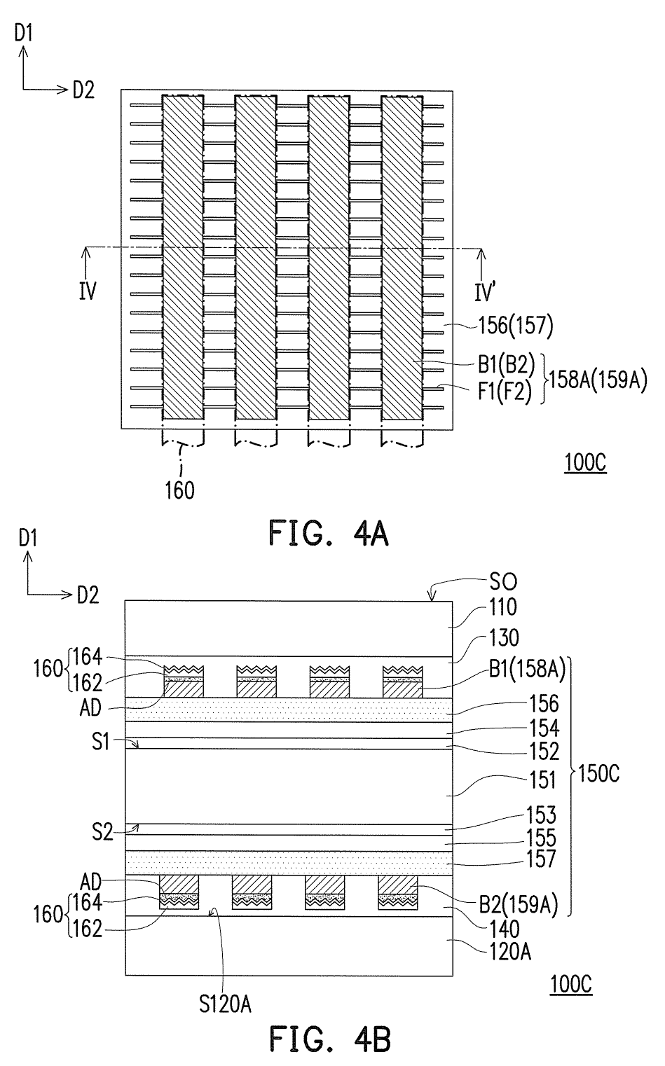

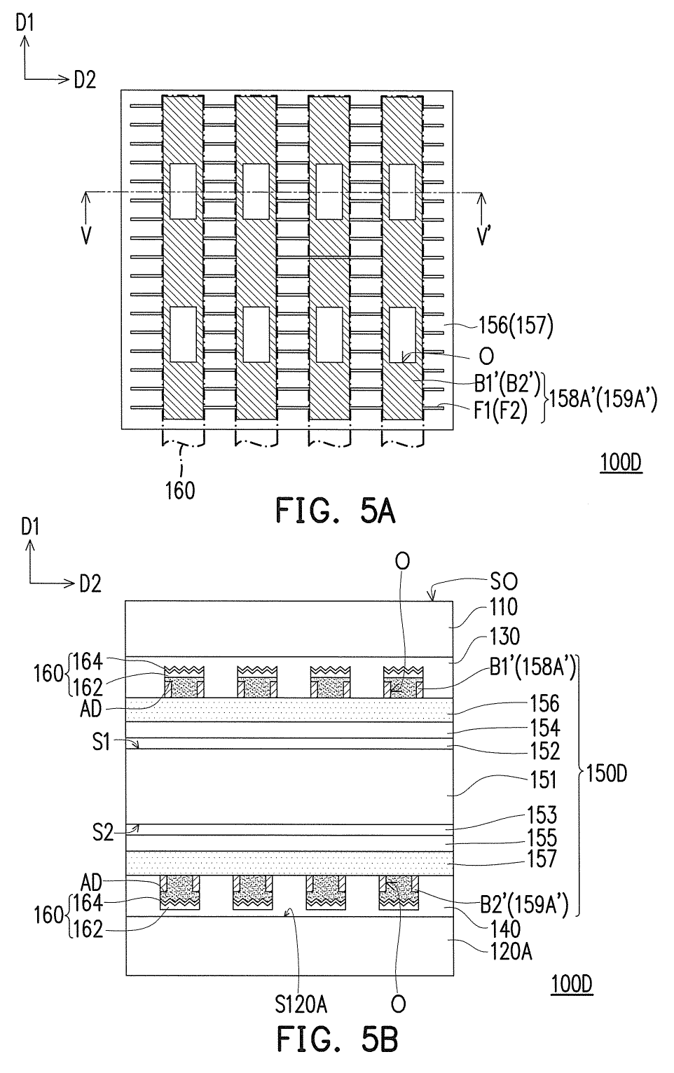

Other implementations of the high power solar cell module are described with reference of FIG. 2 to FIG. 5, where the same or similar elements are denoted by the same or similar referential numbers, and details thereof are not repeated. FIG. 2A is a second partial top view of the high power solar cell module of FIG. 1A. FIG. 2B and FIG. 2C are respectively cross-sectional views viewing along section lines II-II′ and III-III′ of FIG. 2A. FIG. 3A and FIG. 3B are respectively other cross-sectional views viewing along section lines II-II′ and III-III′ of FIG. 2A. FIG. 4A is a third partial top view of the high power solar cell module of FIG. 1A. FIG. 4B is a cross-sectional view viewing along a section line IV-IV′ of FIG. 4A. FIG. 5A is a fourth partial top view of the high power solar cell module of FIG. 1A. FIG. 5B is a cross-sectional view viewing along a section line V-V′ of FIG. 5A. In FIG. 2A, FIG. 4A and FIG. 5A, only one N-type hetero-junction solar cell is schematically illustrated, and the cover plate and the first encapsulation of FIG. 1A are omitted, and dot lines are adopted to indicate positions of the reflective connection ribbons.

Referring to FIG. 2A to FIG. 2C, a main difference between the high power solar cell module 100A and the high power solar cell module 100 of FIG. 1B and FIG. 1C is that each of the N-type hetero-junction solar cells 150A further includes a first metal layer 158. The first metal layer 158 is disposed on the first transparent conductive layer 156, and the reflective connection ribbons 160 are respectively fixed on the first metal layer 158 through the thermosetting conductive adhesive layer AD.

In order to reduce a proportion that the first metal layer 158 shields the light beam, the first metal layer 158 may have a patterned design. Referring to FIG. 2A, the first metal layer 158 may include a plurality of first finger-like electrodes F1. The first finger-like electrodes F1 are arranged along the first direction D1, and, for example, respectively extend along the second direction D2. The reflective connection ribbons 160 can be respectively fixed on the first finger-like electrodes F1 through the thermosetting conductive adhesive layer AD, and each of the reflective connection ribbons 160 covers a part of region of each of the first finger-like electrodes F1.

Moreover, each of the N-type hetero-junction solar cells 150A may further includes a second metal layer 159. The second metal layer 159 is configured on the second transparent conductive layer 157, and the reflective connection ribbons 160 are respectively fixed on the second metal layer 159 through the thermosetting conductive adhesive layer AD. Under the structure of double-side light reception, the second metal layer 159 may have a patterned design, so as to reduce the proportion that the second metal layer 159 shields the light beam. The patterned design of the second metal layer 159 is similar to the patterned design of the first metal layer 158, though the invention is not limited thereto. Referring to FIG. 2A, the second metal layer 159 may include a plurality of second finger-like electrodes F2. The second finger-like electrodes F2 are arranged along the first direction D1, and, for example, respectively extend along the second direction D2, for example. The reflective connection ribbons 160 can be respectively fixed on the second finger-like electrodes F2 through the thermosetting conductive adhesive layer AD, and each of the reflective connection ribbons 160 covers a part of region of each of the second finger-like electrodes F2.

Referring to FIG. 3A and FIG. 3B, a main difference between the high power solar cell module 100B and the high power solar cell module 100A of FIG. 2B and FIG. 2C is that the high power solar cell module 100B is a single-side light receiving solar cell module. Moreover, the high power solar cell module 100B may adopt the back plate 120 of FIG. 1C, so as to improve the light usage rate, though the invention is not limited thereto.

Referring to FIG. 4A and FIG. 4B, a main difference between the high power solar cell module 100C and the high power solar cell module 100A of FIG. 2B and FIG. 2C is that the first metal layer 158A of each of the N-type hetero-junction solar cells 150C further includes at least one first bus electrode B1. In FIG. 4A, the first metal layer 158A includes two first bus electrodes B1, though the invention is not limited thereto. The first bus electrodes B1 respectively extend along the first direction D1, and are arranged along the second direction D2, for example. The reflective connection ribbons 160 are respectively fixed on the first bus electrodes B1 of the N-type hetero-junction solar cells 150C through the thermosetting conductive adhesive layer AD. In the embodiment, the first bust electrodes B1 and the reflective connection ribbons 160 have the same width, though the invention is not limited thereto.

Moreover, under the structure of double-side light reception, the second metal layer 159A may further include at least one second bus electrode B2. In FIG. 4A, the second metal layer 158B includes two second bus electrodes B2, though the invention is not limited thereto. The second bus electrodes B2 respectively extend along the first direction D1, and are arranged along the second direction D2, for example. The reflective connection ribbons 160 are respectively fixed on the second bus electrodes B2 of the N-type hetero-junction solar cells 150C through the thermosetting conductive adhesive layer AD. In the embodiment, the second bust electrodes B2 and the reflective connection ribbons 160 have the same width, though the invention is not limited thereto.

Referring to FIG. 5A and FIG. 5B, a main difference between the high power solar cell module 100D and the high power solar cell module 100C of FIG. 4A and FIG. 4B is that each of the first bus electrodes B1′ of the first metal layer 158A′ and each of the second bus electrodes B2′ of the second metal layer 159A′ of each of the N-type hetero-junction solar cells 150D further includes at least one opening O. In FIG. 5A, each of the first bus electrodes B1′ and each of the second bus electrodes B2′ respectively include two openings O, though the number and configuration locations of the openings are not limited by the invention. For example, the openings O may extend to the edge of each of the first bus electrodes B1′ or each of the second bus electrodes B2′ along a direction parallel to the second direction D2, so that each of the first bus electrodes B1′ or each of the second bus electrodes B2′ is discontinuous (i.e., forms a hopping island bus electrode). After the reflective connection ribbons 160 are fixed on the first bus electrodes B1′ and the second bus electrodes B2′ through the thermosetting conductive adhesive layer AD, the thermosetting conductive adhesive layer AD are partially filled into the openings O.

In another embodiment, under the structure of single-side light reception, the high power solar cell module 100D may adopt the back plate 120 of FIG. 1C, so as to improve the light usage rate, though the invention is not limited thereto.

In summary, since the N-type hetero-junction solar cells have a high photoelectric conversion efficiency, and the triangle columnar structures of the reflective connection ribbons avail improving the light usage rate, the high power solar cell module of the invention may have a high output power.

It will be apparent to those skilled in the art that various modifications and variations can be made to the structure of the invention without departing from the scope or spirit of the invention. In view of the foregoing, it is intended that the invention cover modifications and variations of this invention provided they fall within the scope of the following claims and their equivalents.

What is claimed is:

1. A high power solar cell module, comprising:
a cover plate;
a back plate, opposite to the cover plate;
a first encapsulation, located between the cover plate and the back plate;
a second encapsulation, located between the first encapsulation and the back plate;
a plurality of N-type hetero-junction solar cells, located between the first encapsulation and the second encapsulation; and
a plurality of reflective connection ribbons, located between the first encapsulation and the second encapsulation, and any two adjacent N-type hetero-junction solar cells being connected in series along a first direction by at least one of the reflective connection ribbons, wherein each of the reflective connection ribbons has a plurality of triangle columnar structures, and each of the triangle columnar structures points to the cover plate and extends along the first direction.

2. The high power solar cell module as claimed in claim 1, wherein each of the N-type hetero-junction solar cells includes:
an N-type silicon substrate, having a first surface and a second surface, wherein the second surface is opposite to the first surface and is located between the first surface and the back plate;
a first intrinsic amorphous silicon layer, disposed on the first surface;
a second intrinsic amorphous silicon layer, disposed on the second surface;
a P-type heavily doped hydrogenated amorphous silicon layer, disposed on the first intrinsic amorphous silicon layer;
an N-type heavily doped hydrogenated amorphous silicon layer, disposed on the second intrinsic amorphous silicon layer;
a first transparent conductive layer, disposed on the P-type heavily doped hydrogenated amorphous silicon layer; and
a second transparent conductive layer, disposed on the N-type heavily doped hydrogenated amorphous silicon layer.

3. The high power solar cell module as claimed in claim 2, wherein the reflective connection ribbons are respectively fixed on the first transparent conductive layer and the second transparent conductive layer through a thermosetting conductive adhesive layer.

4. The high power solar cell module as claimed in claim 2, wherein each of the N-type hetero-junction solar cells further comprises:
a first metal layer, disposed on the first transparent conductive layer, and the first metal layer comprises a plurality of first finger-like electrodes arranged along the first direction.

5. The high power solar cell module as claimed in claim 4, wherein the reflective connection ribbons are respectively fixed on the first finger-like electrodes through a thermosetting conductive adhesive layer.

6. The high power solar cell module as claimed in claim 4, wherein the first metal layer further comprises at least one first bus electrode, each first bus electrode extends along the first direction, and the reflective connection ribbons are respectively fixed on the first bus electrodes of the N-type hetero-junction solar cells through a thermosetting conductive adhesive layer.

7. The high power solar cell module as claimed in claim 6, wherein each first bus electrode comprises at least one opening.

8. The high power solar cell module as claimed in claim 4, wherein each of the N-type hetero-junction solar cells further comprises:
a second metal layer, disposed on the second transparent conductive layer, and the reflective connection ribbons being respectively fixed on the second metal layer through a thermosetting conductive adhesive layer.

9. The high power solar cell module as claimed in claim 8, wherein the second metal layer comprises a plurality of second finger-like electrodes arranged along the first direction.

10. The high power solar cell module as claimed in claim 9, wherein the reflective connection ribbons are respectively fixed on the second finger-like electrodes through the thermosetting conductive adhesive layer.

11. The high power solar cell module as claimed in claim 9, wherein the second metal layer further comprises at least one second bus electrode, each second bus electrode extends along the first direction, the reflective connection ribbons are respectively fixed on the second bus electrodes of the N-type hetero-junction solar cells through the thermosetting conductive adhesive layer.

12. The high power solar cell module as claimed in claim 11, wherein each second bus electrode comprises at least one opening.

13. The high power solar cell module as claimed in claim 1, wherein a surface of the back plate facing the cover plate has a plurality of microstructures, the microstructures reflect a light beam entering the high power solar cell module from the cover plate, and the light beam is reflected to one of the N-type hetero-junction solar cells from the cover plate through total internal reflection.

14. The high power solar cell module as claimed in claim 1, wherein a width of each of the reflective connection ribbons ranges between 0.5 mm and 1.5 mm, and a thickness of each of the reflective connection ribbons ranges between 0.15 mm and 0.3 mm.

15. The high power solar cell module as claimed in claim 1, wherein each of the reflective connection ribbons further has a reflective layer, the reflective layer is disposed on the triangle columnar structures, and a reflectivity of the reflective layer is higher than 60%, and a thickness of the reflective layer ranges between 0.3 μm and 10 μm.

16. The high power solar cell module as claimed in claim 15, wherein the reflective layer is a silver reflective layer.
